(19) United States
(12) Patent Application Publication
(10) Pub. No.: US 2005/0208394 A1
(43) Pub. Date: Sep. 22, 2005

(54) Dye-containing curable composition, color filter and method of producing the color filter

(75) Inventor: Nobuo Suzuki, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/078,290

(22) Filed: Mar. 14, 2005

(30) Foreign Application Priority Data
Mar. 16, 2004 (JP) 2004-75082

(51) Int. Cl. G03F 9/00

(52) U.S. Cl. 430/7

(57) ABSTRACT

A dye-containing curable composition including at least (A) an alkali-soluble resin, (B) a dye, and (C) a photosensitive compound, the dye being a phthalocyanine compound represented by the following Formula (I): 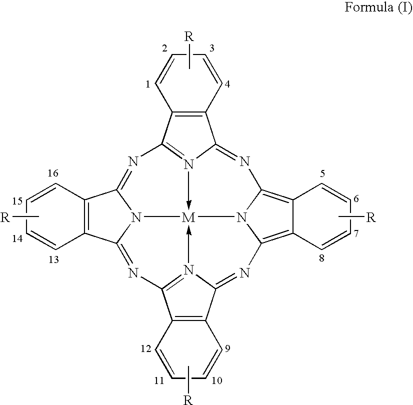 wherein M represents a metal atom, a metal oxide, a metal chloride, or a hydrogen atom, R represents a heterocyclic group containing, as heteroatoms, two or more nitrogen atoms or one or more of each of nitrogen and sulfur atoms, and the four R's are respectively bonded to a carbon atom at the α-positions (in Formula (I), 1 or 4, 5 or 8, 9 or 12, and 13 or 16) or at the β-positions (in Formula (I), 2 or 3, 6 or 7, 10 or 11, and 14 or 15) in a phthalocyanine nucleus at the same time.

### CROSS-REFERENCE TO RELATED APPLICATION

This application claims priority under 35 USC 119 from Japanese Patent Application No. 2004-075082, the disclosure of which is incorporated by reference herein.

### BACKGROUND OF THE INVENTION

1. Field of the Invention

The present invention relates to a dye-containing curable composition including a dye, especially, a phthalocyanine type dye, as a coloring component, and also relates to a color filter and a method of producing the color filter.

2. Description of the Related Art

Known methods of producing color filters used in liquid crystal display elements, solid-state imaging devices and the like include dyeing, printing, electrodeposition, and pigment dispersion methods.

The dyeing method is a method of producing a color filter involving dyeing a dyeing base material, which is made of a natural resin such as a gelatin, glue, or casein, or a synthetic resin such as amine modified polyvinyl alcohol, with a dye such as an acid dye. However, since the dyeing method uses a dye as the coloring material, it has problems relating to light fastness, heat resistance, moisture resistance and the like. Besides these problems, there is an undesirable uneveness in color that occurs easily as it is difficult to uniformly control dyeing and fixing characteristics when producing a large-size color filter. A further problem is that a reserve printing layer is needed in a dyeing operation, which complicates the dyeing process.

The electrodeposition method is a method of producing a color filter in the following manner: transparent electrodes are preformed in a given pattern, a resin containing pigments dissolved or dispersed in a solvent is ionized, and a voltage is applied to form a color image pattern-wise. In this electrodeposition method, a photolithographic process that includes both film formation of transparent electrodes for forming a color filter in addition to the transparent electrodes for display and an etching process are required. However, during this process, development of an electric short circuit brings about a line defect, resulting in a reduced yield. It is also difficult in principle to apply this method to arrangements other than a stripe arrangement, for example, a mosaic arrangement, and it is also difficult to control the transparent electrodes.

The printing method is a simple method of producing a color filter by printing such as with offset printing using ink prepared by dispersing pigments in a thermoplastic resin or ultraviolet curable resin. However, ink which can be used in this method is highly viscous and filtering of the ink is therefore difficult. Also, defects easily arise from dust, foreign matter, and gelling of the ink binder. Further, this method encounters problems with positional accuracy, accuracy of line width, and plane smoothness associated with printing accuracy.

The pigment dispersion method is a method of producing a color filter with a photolithographic process using a color radiation-curable composition obtained by dispersing pigments in various photosensitive compositions. The advantage of this method is that the composition used is stable with respect to light, heat, and the like owing to its use of pigments. Also, since patterning is carried out with a photolithographic process, positional accuracy is sufficiently secured, and the pigment dispersion method is suited to the production of large-scale and highly accurate color display color filters.

A pigment dispersion method is disclosed that uses a negative type photosensitive composition using an alkali-soluble resin in combination with a photopolymerizable monomer and a photopolymerization initiator (see, for example, Japanese Patent Application Laid-Open (JP-A) No. 1-102469). Recently, however, development has been desired of more highly precise color filters for solid-state imaging devices. A problem with conventional pigment dispersion methods is that the resolution basically does not improve due to the pigments existing in the state of particles having a certain size, and color unevenness being caused by coarse pigment particles. This method is therefore unsuitable to applications that require a fine pattern, such as with solid-state imaging devices.

To attain a color filter having higher resolution, research has been carried out in technologies using dyes as colorants. Two types of photosensitive composition using dyes have been proposed, one being a positive type using a naphthoquinonediazide compound or the like as a photosensitive material (see, for example, JP-A No. 2-127602) and another being a negative type using a photopolymerization initiator (together with a crosslinking agent) as a photosensitive material (see, for example, JP-A No. 6-75375). These photosensitive color compositions, however, have problems such as with solubility in a solvent and with the dyes having low heat resistance and light fastness.

In view of this situation, phthalocyanine-type compounds have been given as examples of dyes superior in heat resistance and light fastness. These phthalocyanine-type dyes, however, have poor solvent solubility, which poses practical problems. For example, it is difficult to produce a color filter with methods that include applying a composition containing a phthalocyanine. Attempts to improve this solvent solubility have encountered problems such as reduced heat resistance and light fastness. Thus, neither dye-containing curable compositions nor color filters have been provided which contain dyes having high solvent solubility, heat resistance, light fastness, that are free from precipitation of dyes, and have high weatherability against light and heat.

In contrast, as examples of phthalocyanine-type compounds improved in solvent solubility, there are compounds obtained by introducing a long-chain alkyl group, or a long-chain alkyl group (see, for example, JP-A No. 1-180865) or a sulfonic acid amide group (see, for example, JP-A No. 3-195783) through a functional group such as an alkoxy group, ester group, polyether group or thioether group. However, these phthalocyanine-type compounds have a low absorption coefficient, and a disadvantage is that when formed as a film, the absorption coefficient in the long wavelength region is reduced by the association of phthalocyanine molecules.

Although a curable composition containing a dye is useful in applications such as with solid-state imaging devices of which high accuracy and uniform color are demanded, no technique has so far been provided for a system containing a phthalocyanine type compound as the dye which has sufficient solubility of composition components such as dyes, stability of color density and hue with respect to light and heat (weatherability), and spectral characteristics (for example, hue suitable to a color filter).

### SUMMARY OF THE INVENTION

The present invention has been made in view of the above described circumstances and provides a dye-containing curable composition which has good spectral characteristics (absorption coefficient) when obtaining a cyan color, and, for example, a green color by combining a yellow dye type or a blue color by combining a violet dye type, has high solvent solubility, and is superior in heat resistance and light fastness. The invention also provides a color filter which has a sharp pattern (for example, good rectangular shape) and is structured to have high resolution, has spectral characteristics exhibiting good hue, and is superior in heat resistance and light fastness. Further, the invention provides a method of producing the color filter that allows the color filter to be produced at a high level of productivity.

A first aspect of the invention is to provide a dye-containing curable composition comprising at least (A) an alkali-soluble resin, (B) a dye, and (C) a photosensitive compound, wherein the dye is a phthalocyanine compound represented by the following Formula (I).

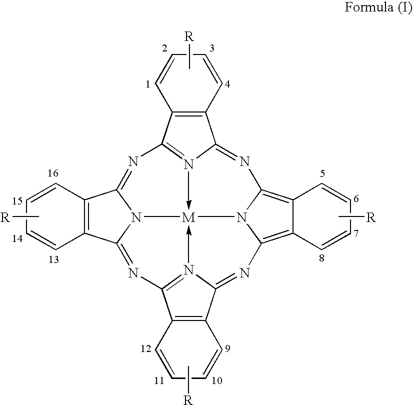

In Formula (I), M represents a metal atom, a metal oxide, a metal chloride, or a hydrogen atom. R represents a heterocyclic group containing, as heteroatoms, two or more nitrogen atoms, or one or more of each of nitrogen and sulfur atoms. The four R's are respectively bonded (substituted) to a carbon atom at the α-positions (in Formula (I), 1 or 4, 5 or 8, 9 or 12, and 13 or 16) or at the β-positions (in Formula (I), 2 or 3, 6 or 7, 10 or 11, and 14 or 15) in a phthalocyanine nucleus (skeleton) at the same time. The numbers 1 to 16 in Formula (I) indicate the positions of peripheral carbon atoms.

A second aspect of the invention is to provide a color filter comprising a phthalocyanine compound represented by the following Formula (I).

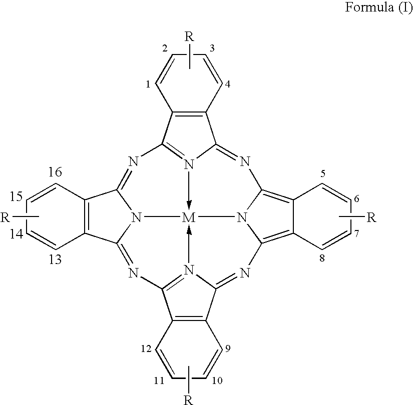

In Formula (I), like the above, M represents a metal atom, a metal oxide, metal chloride, or a hydrogen atom. R represents a heterocyclic group containing, as heteroatoms, two or more nitrogen atoms, or one or more of each of nitrogen and sulfur atoms. The four R's are respectively bonded to a carbon atom at the α-positions (in Formula (I), 1 or 4, 5 or 8, 9 or 12, and 13 or 16) or at the β-positions (in Formula (I), 2 or 3, 6 or 7, 10 or 11, and 14 or 15) in a phthalocyanine nucleus (skeleton) at the same time. The numbers 1 to 16 in Formula (I) indicate the positions of peripheral carbon atoms.

A third aspect of the invention is to provide a method of producing a color filter, the method comprising applying the dye-containing curable composition according to the first aspect to a support, then exposing the applied composition to light through a mask, and then developing to form a pattern image.

### BRIEF DESCRIPTION OF THE DRAWING

FIG. 1 is a graph showing a spectrum of a dye resist film formed by application to a surface in Example 1 of the invention.

### DETAILED DESCRIPTION OF THE INVENTION

A dye-containing curable composition, a color filter (preferably using the dye-containing curable composition of the invention), and a method of producing the color filter of the present invention will be hereinafter explained in detail.

Dye-Containing Curable Composition

The dye-containing curable composition of the invention contains at least (A) an alkali-soluble resin, (B) a dye, and (C) a photosensitive compound, and generally contains (D) a solvent, wherein a phthalocyanine compound represented by the following Formula (I) is contained as the dye. The dye-containing curable composition of the invention can be structured as a positive type when it contains a naphthoquinonediazide compound as the photosensitive compound (C), and as a negative type when it contains a photopolymerization initiator as the photosensitive compound (C). (E) A crosslinking agent is generally further contained in a negative type. When the composition is made to have a positive type structure, it may also further contain the crosslinking agent (E) (preferably together with a photopolymerization initiator). The composition may contain other components as needed.

First, the dye (B) which is a characteristic of the invention will be explained.

—Dye (B)—

In the invention, the dye-containing curable composition contains at least one kind of phthalocyanine compound (dye) represented by the following Formula (I) as a coloring component. This dye exhibits a good hue for use as a cyan and the following colors are obtained through combination with other color dye types: for example, when this dye is combined with a yellow dye type, a green with a good hue is obtained, and when the dye is combined with a violet dye type, a blue with a good hue is obtained. Also, the dye has good solubility (particularly in a solvent) during preparation of the dye-containing curable composition, is stable without any precipitation over time when either in a liquid preparation of the dye-containing curable composition or in a coating film obtained by coating the liquid preparation, and is also superior in weatherability with respect to heat and light (light fastness and heat resistance). Pattern forming ability is also improved. For example, a color pattern (color pixels) constituting a color filter can be formed into a pattern shape that has a good rectangular pattern cross-section.

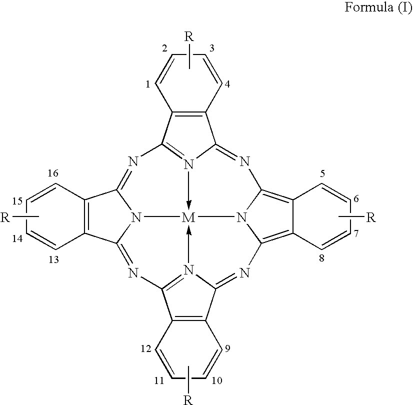

In Formula (I), M represents a metal atom, a metal oxide, a metal chloride, or a hydrogen atom. Specific examples of M include metals such as Mn, Fe, Co, Ni, Cu, Zn, Pd, Cd and Mg; metal oxides such as TiO and VO; metal chlorides such as AlCl; and H₂ (two atoms of hydrogen).

In Formula (I), R represents a heterocyclic group containing, as heteroatoms, two or more nitrogen atoms, or one or more of each of nitrogen and sulfur atoms. Here, the four R's are respectively bonded with a carbon atom at an α-position (in Formula (I), 1 or 4, 5 or 8, 9 or 12, and 13 or 16) or at a β-position (in Formula (I), 2 or 3, 6 or 7, 10 or 11, and 14 or 15) in a phthalocyanine nucleus at the same time (the phthalocyanine nucleus is substituted by the four R's at the α-positions or at the β-positions). The numbers 1 to 16 in Formula (I) indicate the positions of peripheral carbon atoms.

Preferable examples of R include substituted or unsubstituted pyrazolyl groups, imidazolyl groups, 1,2,3-triazolyl groups, 1,2,4-triazolyl groups, tetrazolyl groups, indazolyl groups, benzimidazolyl groups, benzotriazolyl groups, thiazolyl groups, benzothiazolyl groups, purinyl groups, and pyrimidinyl groups.

When R is substituted, examples of the substituent include straight-chain or branched alkyl groups or alkoxy groups having 1 to 12 carbon atoms which may have a substituent; amino groups; substituted or unsubstituted alkyl groups; substituted secondary or tertiary amino groups; sulfonylamide groups; alkyl substituted sulfonylamide groups; halogen atoms such as chlorine, bromine, and fluorine; nitro groups; hydroxyl groups; cyano groups; and phenyl, phenoxy, or thiophenoxy groups which may have a substituent.

Among the examples of R, pyrazolyl groups, 3-methylpyrazolyl groups, 3,5-dimethylpyrazolyl groups, benzimidazolyl groups, 5,6-dimethylbenzimidazolyl groups, and 4,6-dimethylpyrimidinyl groups are particularly preferable.

The substituted position of R in the phthalocyanine skeleton in Formula (I) may be any of the α-positions and β-positions in the phthalocyanine skeleton. The α-position-substituted compound in which the four R's are bonded to the α-position carbon atoms is preferable in that it has a larger effect on the prevention of molecular association and in that the absorption coefficient of the film is raised.

Specific examples (exemplified compounds (1) to (32)) of the phthalocyanine compound represented by Formula (I) are shown in Table 1. However, these examples are not intended to be limiting of the invention.

TABLE 1

| | | Substituted | |
|---|---|---|---|
| | R | position of R | M |
| Exemplified compound(1) | Benzimidazolyl | α | Zn |
| Exemplified compound(2) | Benzimidazolyl | β | Zn |
| Exemplified compound(3) | 3,5-dimethylpyrazolyl | α | Zn |
| Exemplified compound(4) | 3,5-dimethylpyrazolyl | β | Zn |
| Exemplified compound(5) | Benzimidazolyl | α | Co |
| Exemplified compound(6) | Benzimidazolyl | β | Co |
| Exemplified compound(7) | Benzimidazolyl | α | Cu |
| Exemplified compound(8) | Benzimidazolyl | β | Cu |
| Exemplified compound(9) | 3-methylpyrazolyl | α | Zn |
| Exemplified compound(10) | 3-dimethylpyrazolyl | β | Zn |
| Exemplified compound(11) | 3-methylpyrazolyl | α | Cu |
| Exemplified compound(12) | 3-methylpyrazolyl | β | Cu |
| Exemplified compound(13) | 3,5-dimethylpyrazolyl | α | Cu |
| Exemplified compound(14) | 3,5-dimethylpyrazolyl | β | Cu |
| Exemplified compound(15) | 3,5-dimethylpyrazolyl | α | Ni |
| Exemplified compound(16) | 3,5-dimethylpyrazolyl | β | Ni |
| Exemplified compound(17) | 3,5-dimethylpyrazolyl | α | Fe |
| Exemplified compound(18) | 3,5-dimethylpyrazolyl | α | Co |
| Exemplified compound(19) | 3,5-dimethylpyrazolyl | α | VO |
| Exemplified compound(20) | 3,5-dimethylpyrazolyl | α | H2 |
| Exemplified compound(21) | 3,5-dimethylpyrazolyl | α | Mn |
| Exemplified compound(22) | 3,5-dimethylpyrazolyl | α | Pd |
| Exemplified compound(23) | 3,5-dimethylpyrazolyl | α | Mg |
| Exemplified compound(24) | 3,5-dimethylpyrazolyl | α | TiO |
| Exemplified compound(25) | 3,5-dimethylpyrazolyl | β | Fe |
| Exemplified compound(26) | 3,5-dimethylpyrazolyl | β | Co |
| Exemplified compound(27) | 3,5-dimethylpyrazolyl | β | VO |
| Exemplified compound(28) | 3,5-dimethylpyrazolyl | β | H2 |
| Exemplified compound(29) | 3,5-dimethylpyrazolyl | β | Mn |
| Exemplified compound(30) | 3,5-dimethylpyrazolyl | β | Pd |
| Exemplified compound(31) | 3,5-dimethylpyrazolyl | β | Mg |
| Exemplified compound(32) | 3,5-dimethylpyrazolyl | β | TiO |

The phthalocyanine compound represented by Formula (I) may be synthesized by reacting corresponding phthalonitrile (together with a metal salt according to the need) in the presence of 1,8-diazabicyclo[5,4,0]-7-undecene or the like which is a strong organic base. in an alcoholic solvent.

The method of synthesizing the phthalocyanine compound represented by Formula (I) will be explained taking Synthetic Examples (Synthetic Examples 1 to 4) for synthesizing the exemplified compounds (1) to (4) as examples.

### SYNTHETIC EXAMPLE 1

### Synthesis of Exemplified Compound (1)

1) Synthesis of a Phthalonitrile Derivative

4.5 g of benzimidazole, 5.5 g of 3-nitrophthalonitrile, 8.5 g of potassium carbonate anhydride and 30 ml of dimethylsulfoxide were prepared and reacted at 72° C. for 4 hours. 300 ml of water was added to the reaction product to precipitate crystals, which were then collected and dried to obtain 7.3 g of 3-(1-benzimidazolyl)phthalonitrile (phthalonitrile derivative). Analytical data of this phthalonitrile derivative are as follows.

IR spectrum (KBr): 2320 cm⁻¹ (vCN)

Mass spectrum: 244 (M⁺)
Melting point: 220° C.
   2) Cyclizing Reaction

0.7 g of zinc chloride, 4.2 g of DBU(1,8-diazabicyclo[5,4,0]-7-undecene) and 20 ml of 1-pentanol were added to 4.0 g of phthalonitrile derivative obtained above and the mixture was reacted at 100° C. for 11 hours in a nitrogen atmosphere. The obtained reaction product was filtered and then was washed with methanol to obtain 2.9 g of a crude dye. This crude dye was purified by a column chromatography to obtain 0.9 g of a purified dye, tetra-α-(1-benzimidazolyl)zinc phthalocyanine (exemplified compound (1)).

### SYNTHETIC EXAMPLE 2

### Synthesis of Exemplified Compound (2)

Tetra-β-(1-benzimidazolyl)zinc phthalocyanine (exemplified compound (2)) was obtained in the same manner as in Synthetic Example 1 except that 4-nitrophthalonitrile was used as the raw material in place of 3-nitrophthalonitrile in the reaction 1) of Synthetic Example 1.

### SYNTHETIC EXAMPLE 3

### Synthesis of Exemplified Compound (3)

Tetra-α-(3,5-dimethylpyrazolyl)zinc phthalocyanine (exemplified compound (3)) was obtained in the same manner as in Synthetic Example 1 except that 3,5-dimethylpyrazole was used in place of benzimidazole in the reaction 1) of Synthetic Example 1.

### SYNTHETIC EXAMPLE 4

### Synthesis of Exemplified Compound (4)

Tetra-β-(3,5-dimethylpyrazolyl)zinc phthalocyanine (exemplified compound (4)) was obtained in the same manner as in Synthetic Example 3 except that 4-nitrophthalonitrile was used as the raw material in place of 3-nitrophthalonitrile in the reaction 1) of Synthetic Example 3.

In the dye-containing curable composition of the invention, phthalocyanine compounds represented by Formula (I) may be used either singly or in combinations of two of more thereof as the dye. Also, conventional dyes may be used in combination with the phthalocyanine compound represented by Formula (I).

Any dye may be used as the aforementioned conventional known dye without any particular limitation insofar as it is dissolved in a required amount in a solvent (hereinafter also referred to as an organic solvent) and an appropriate dye may be selected according to the spectral absorption that is required. Examples of the type of dye include acid dyes, basic dyes, dispersion dyes, and those which are reaction products of acid dyes and basic compounds or of basic dyes and acid compounds and which are made to be soluble in organic dyes.

It is necessary for the conventional dye to have a spectrum desirable for a color filter, to be dissolved in a required concentration in solvents (which will be explained later) or solutions containing an alkali-soluble resin, and to be free from precipitation and coagulation over time. The conventional dye may be appropriately selected from, for example, C.I. Solvent Colors described in a color index. Also, the conventional dye may be selected from known oil-soluble dyes, acid dyes, dispersion dyes, reactive dyes, direct dyes, etc. which conform to the dye of the invention in solvent solubility and spectrum.

Whether a dye is soluble in an organic solvent or not is judged by whether an amount of 1% or more by weight is soluble in the solvent or not. However, this does not apply in a case where solubility is increased by mixing a dye with another component. In such a case, a dye may be used even if the solubility thereof is less than 1% depending on its amount.

The content of the phthalocyanine compound represented by Formula (I) (and a conventional dye according to the need) in the dye-containing curable composition is preferably 1 to 80 mass % and more preferably 3 to 50 mass % based on the total solid (mass) of the composition. The smaller the ratio of the dye is, the more preferable from the viewpoint of sensitivity and developing ability as long as the spectral characteristics can be satisfied.

Next, the compounded components (A) and (C) to (E) and other components will be explained in detail.

—(A) Alkali-Soluble Resin—

The dye-containing curable composition of the invention contains at least one alkali-soluble resin. As the alkali-soluble resin, those which are linear organic high-molecular polymers, soluble in an organic solvent and can be developed using an aqueous weak alkali solution are preferable. Examples of the linear organic high-molecular polymer include polymers having a carboxylic acid at its side chain, for example, methacrylic acid copolymers, acrylic acid copolymers, itaconic acid copolymers, crotonic acid copolymers, maleic acid copolymers and partially esterified maleic acid copolymers as described in each publication of JP-A No. 59-44615, Japanese Patent Application Publication (JP-B) Nos. 54-34327, 58-12577 and 54-25957 and JP-A Nos. 59-53836 and 59-71048. Also, acidic cellulose derivatives having a carboxylic acid at their side chains are useful.

In addition to the above, polymers which have a hydroxyl group and to which an acid anhydride is added, polyhydroxystyrene type resins, polysiloxane type resins, poly(2-hydroxyethyl(meth)acrylate), polyvinylpyrrolidone, polyethylene oxide, polyvinyl alcohol and the like are also useful.

Also, hydrophilic monomers may be copolymerized to obtain the alkali-soluble resins. Examples of these monomers include an alkoxyalkyl(meth)acrylate, hydroxyalkyl(meth)acrylate, glycerol(meth)acrylate, (meth)acrylamide, N-methylolacrylamide, secondary or tertiary alkylacrylamide, dialkylaminoalkyl(meth)acrylate, morpholine(meth)acrylate, N-vinylpyrrolidone, N-vinylcaprolactam, vinylimidazole, vinyltriazole, methyl(meth)acrylate, ethyl(meth)acrylate, branched or straight-chain propyl(meth)acrylate, branched or straight-chain butyl(meth)acrylate and phenoxyhydroxypropyl(meth)acrylate.

Other than the above, monomers containing a tetrahydrofurfuryl group, a phosphoric acid part, a phosphate part, a quaternary ammonium salt part, an ethyleneoxy chain, a propyleneoxy chain, sulfonic acid or its salt part, a morpholino ethyl or the like are also useful.

Also, the binder may have a polymerizable group at its side chain to improve crosslinking efficiency and polymers containing an aryl group, (meth)acryl group, allyloxyalkyl group or the like at their side chains are also useful. Also, alcohol-soluble nylon, a polyether of 2,2-bis-(4-hydroxyphenyl)-propane and epichlorohydrin and the like are also useful to raise the strength of a cured film.

Among these alkali-soluble resins, polyhydroxystyrene type resins, polysiloxane type resins, acryl type resins, acrylamide type resins and acryl/acrylamide copolymer resins are preferable from the viewpoint of heat resistance, and acryl type resins, acrylamide type resins and acryl/acrylamide copolymer resins are preferable from the viewpoint of controlling developing ability.

As the acryl type resin, copolymers made of monomers selected from benzyl(meth)acrylate, (meth)acrylic acid, hydroxyethyl(meth)acrylate, (meth)acrylamide and allyl(meth)acrylate are preferable.

Alkali-soluble phenol resins are also useful. Namely, Given as examples of the alkali-soluble resin having a phenolic hydroxyl group include polyhydroxystyrene type resins. Specific examples of the alkali-soluble resin include p-hydroxystyrene resin, m-hydroxystyrene resin, o-hydroxystyrene resin, copolymers of these resins, copolymers of hydroxystyrene and styrene, copolymers of hydroxystyrene and acetoxystyrene and copolymers of hydroxystyrene and the aforementioned (meth)acryl type monomers.

Also, novolac resins or vinyl polymers are also given as examples.

Examples of the novolac resins include those obtained by condensing phenols and aldehydes in the presence of an acid catalyst. Examples of the phenols include phenol, cresol, ethylphenol, propyl phenol, butyl phenol, xylenol, phenylphenol, catechol, resorcinol, pyrogallol, naphthol and bisphenol A. These phenols may be used either singly or in combinations of two or more. Examples of the aldehydes include formaldehyde, paraformaldehyde, acetaldehyde, propionaldehyde and benzaldehyde.

Specific examples of the novolac resin include condensed products of methacresol, paracresol or mixtures of them and formalin.

As the alkali-soluble resin, polymers having a number average molecular weight Mn (measured by a GPC method and based on polystyrene) of 1000 to 2×10⁵ are preferable, polymers having a number average molecular weight Mn of 2000 to 1×10⁵ are more preferable and polymers having a number average molecular weight Mn of 4000 to 5×10⁴ are particularly preferable.

The molecular weight distribution (weight average molecular weight Mw/number average molecular weight Mn) of the alkali-soluble resin is preferably 1.6 to 1.05, and more preferably 1.4 to 1.1 in the point that the rectangular exactness of a profile of an developed image (pattern) can be maintained. In order to obtain the molecular weight distribution falling in the above range, it is preferable to directly synthesize a resin having a narrow molecular weight distribution by applying a known polymerization method (e.g., a living anion polymerization method, living cation polymerization method and living radical polymerization method). However, besides the above methods, a solvent fractionation method (after a resin is dissolved in a rich solvent, the solution is mixed in a poor solvent to precipitate only high molecular weight components, thereby obtaining a resin having a narrow molecular weight distribution) or a method such as molecular weight fractionation using column chromatography or fractionation using a supercritical fluid may be applied.

The content of the alkali-soluble resin in the dye-containing curable composition is preferably 10 to 90 mass %, more preferably 20 to 80 mass %, and particularly preferably 30 to 70 mass % based on the total solid content (mass).

—(C) Photosensitive Compound—

The dye-containing curable composition of the invention contains at least one photosensitive compound. As the photosensitive compound, a naphthoquinonediazide compound is preferable when the dye-containing curable composition is structured as a positive type and a photopolymerization initiator is preferable when the dye-containing curable composition is structured as a negative type.

(Naphthoquinonediazide Compound)

In order to obtain a positive type dye-containing curable composition, it is preferable to use a naphthoquinonediazide compound which is to be used as a semiconductor photoresist sensitive to g-rays or i-rays. Examples of the naphthoquinonediazide compound include o-naphthoquinonediazide-5-sulfonate, o-naphthoquinonediazide-5-sulfonic acid amide, o-naphthoquinonediazide-4-sulfonate, and o-naphthoquinonediazide-4-sulfonic acid amide. These esters and amides may be produced using, for example, phenol compounds represented by Formula (I) in each publication of JP-A Nos. 2-84650 and 3-49437 by a known method.

The phenol compound preferably has at least two and preferably three or more phenolic hydroxyl groups in one molecule in the point that sufficient resistance to an alkali developer before exposure and high developing ability after exposure can be provided. Also, it is preferable not to make all hydroxyl groups in the molecule into naphthoquinonedizide sulfonates but to leave a part of the hydroxyl groups from the viewpoint of improving solubility in a solvent.

The above alkali-soluble resin and naphthoquinonediazide are generally dissolved in a solvent in a proportion of about 2 to 35 mass % based on the mass of the solvent.

(Photopolymerization Initiator)

When the dye-containing curable composition is structured as a negative type, a photopolymerization initiator is an essential component. Also, the photopolymerization initiator may be further contained in a positive type containing the above naphthoquinonediazide compound and in this case, the hardness of a pattern can be promoted after the pattern is formed.

Any photopolymerization initiator may be used as the above photopolymerization initiator without any particular limitation insofar as it can initiate a crosslinking reaction of a crosslinking agent or polymerization reaction, by exposure. However, the photopolymerization initiator is preferably selected from the viewpoint of, for example, characteristics, initiation efficiency, absorption wavelength, availability, cost and safety. Examples of the photopolymerization initiator include at least one active halogen compound selected from halomethyloxadiazole compounds and halomethyl-s-triazine compounds, 3-aryl substituted coumarin compounds, lophine dimers, benzophenone compounds, acetophenone compounds and their derivatives, cyclopentadiene-benzene-iron complexes and their salts and oxime type compounds.

Examples of the active halogen compounds which are the above halomethyloxadiazole compounds include 2-halomethyl-5-vinyl-1,3,4-oxadiazole compounds described in the publication of JP-B No. 57-6096, 2-trichloromethyl-5-styryl-1,3,4-oxadiazole, 2-trichloromethyl-5-(p-cyanostyryl)-1,3,4-oxadiazole and 2-trichloromethyl-5-(p-methoxystyryl)-1,3,4-oxadiazole.

Examples of the active halogen compounds which are the above halomethyl-s-triazine compounds include vinyl-halomethyl-s-triazine compounds described in the publication of JP-B No. 59-1281, and 2-(naphtho-1-yl)-4,6-bis-halomethyl-s-triazine compounds and 4-(p-aminophenyl)-2,6-di-halomethyl-s-triazine compounds described in the publication of JP-A No. 53-133428.

Specific examples of the active halogen compound include 2,4-bis(trichloromethyl)-6-p-methoxystyryl-s-triazine, 2,6-bis(trichloromethyl)-4-(3,4-methylenedioxyphenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxyethyl)-naphtho-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, 4-[p-N,N-di(ethoxycarbonylmethyl)aminophenyl]-2,6-di(trichloromethyl)-s-triazine, 4-[o-methyl-p-N,N-di(ethoxycarbonylmethyl)aminophenyl]-2,6-di(trichloromethyl)-s-triazine, 4-[p-N,N-di(chloroethyl)aminophenyl]-2,6-di(trichloromethyl)-s-triazine, 4-[o-methyl-p-N,N-di(chloroethyl)aminophenyl]-2,6-di(trichloromethyl)-s-triazine, 4-(p-N-chloroethylaminophenyl)-2,6-di(trichloromethyl)-s-triazine, 4-(p-N-ethoxycarbonylmethylaminophenyl)-2,6-di(trichloromethyl)-s-triazine, 4-[p-N,N-di(phenyl)aminophenyl]-2,6-di(trichloromethyl)-s-triazine, 4-(p-N-chloroethylcarbonylaminophenyl)-2,6-di(trichloromethyl)-s-triazine, 4-[p-N-(p-methoxyphenyl)carbonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonylmethyl)aminophenyl]-2,6-di(trichloromethyl)-s-triazine, 4-[o-bromo-p-N,N-di(ethoxycarbonylmethyl)aminophenyl]-2,6-di(trichloromethyl)-s-triazine, 4-[o-chloro-p-N,N-di(ethoxycarbonylmethyl)aminophenyl]-2,6-di(trichloromethyl)-s-triazine, 4-[o-fluoro-p-N,N-di(ethoxycarbonylmethyl)aminophenyl]-2,6-di(trichloromethyl)-s-triazine, 4-[o-bromo-p-N,N-di(chloroethyl)aminophenyl]-2,6-di(trichloromethyl)-s-triazine, 4-[o-chloro-p-N,N-di(chloroethyl)aminophenyl]-2,6-di(trichloromethyl)-s-triazine, 4-[o-fluoro-p-N,N-di(chloroethyl)aminophenyl]-2,6-di(trichloromethyl)-s-triazine, 4-[m-bromo-p-N,N-di(chloroethyl)aminophenyl]-2,6-di(trichloromethyl)-s-triazine, 4-[m-chloro-p-N,N-di(chloroethyl)aminophenyl]-2,6-di(trichloromethyl)-s-triazine, 4-[m-fluoro-p-N,N-di(chloroethyl)aminophenyl]-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine and 4-(o-fluoro-p-N-chloroethylaminophenyl)-2,6-di(trichloromethyl)-s-triazine.

Other than the above compounds, a TAZ series (e.g., TAZ-104, TAZ-107, TAZ-109, TAZ-110, TAZ-113, TAZ-123, TAZ-140 and TAZ-204) manufactured by Midori Kagaku Co., Ltd., T series (e.g., T-OMS, T-BMP, T-R and T-B) manufactured by PANCHIM Company, IRGACURE series (e.g., IRGACURE 149, IRGACURE 184, IRGACURE 261, IRGACURE 500, IRGACURE 651, IRGACURE819 and IRGACURE 1000) and DAROCURE series (e.g., DAROCURE 1173) manufactured by Ciba Speciality Chemicals Inc., 4,4′-bis(diethylamino)-benzophenone, 2-(O-benzoyloxime)-1-[4-(phenylthio)phenyl]-1,2-octanedione, 2-benzyl-2-dimethylamino-4-morpholinobutyrophenone, 2,2-dimethoxy-2-phenylacetophenone, 2-(o-chlorophenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenylimidazolyl dimer and benzoisopropyl ether are also used usefully.

These photopolymerization initiators may be used with a sensitizer or a photostabilizer.

Specific examples of these sensitizers and photostabilizers include benzoin, benzoinmethyl ether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, 2-ethoxyxanthone, thioxanthone, 2,4-diethylthioxanthone, acridone, 10-butyl-2-chloroacridone, benzyl, dibenzylacetone, p-(dimethylamino)phenylstyryl ketone, p-(dimethylamino)phenyl-p-methylstyryl ketone, benzophenone, p-(dimethylamino)benzophenone (or Michler's ketone), p-(diethylamino)benzophenone, benzoanthrone, benzothiazole type compounds described in the publication of JP-B No. 51-48516 and TINUBIN 1130 and TINUBIN 400.

The dye-containing curable composition of the invention may contain other known initiators besides the above photopolymerization initiators. Specific examples of these known initiators may include vicinal polyketolaldonyl compounds disclosed in the specification of U.S. Pat. No. 2,367,660, α-carbonyl compounds disclosed in each specification of U.S. Pat. Nos. 2,367,661 and 2,367,670, acyloin ethers disclosed in the specification of U.S. Pat. No. 2,448,828, aromatic acyloin compounds substituted by α-hydrocarbon as disclosed in the specification of U.S. Pat. No. 2,722,512, polynuclear quinone compounds described in each specification of U.S. Pat. Nos. 3,046,127 and 2,951,758, a combination of triarylimidazole dimer/p-aminophenyl ketone disclosed in the specification of U.S. Pat. No. 3,549,367 and benzothiazole type compound/trihalomethyl-s-triazine type compound disclosed in the publication of JP-B No. 51-48516.

The total content of the photopolymerization initiator (and the known initiator) is preferably 0.01 to 50 mass %, more preferably 1 to 30 mass % and particularly preferably 1 to 20 mass % based on the solid content (mass) of the polymerizable monomer component (for example, the polymerizable monomer compound given as examples of the crosslinking agent which will be described later).

—(D) Solvent—

When the dye-containing curable composition of the invention is prepared, a solvent may be usually contained. Though no particular limitation is basically imposed on the solvent insofar as the solubility of each component and the coatability of the dye-containing curable composition are satisfied, it is preferably selected in consideration of, particularly, the solubility of the dye and alkali-soluble resin, coatability and safety.

Preferable examples of the solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxy acetate, methyl methoxyacetate, ethyl methoxyacetate, butyl methoxyacetate, methyl ethoxyacetate and ethyl ethoxyacetate;
alkyl 3-oxypropionates such as methyl 3-oxypropionate and ethyl 3-oxypropionate, e.g., methyl 3-methoxypropionate, ethyl 3-methoxypropionate, methyl 3-ethoxypropionate and ethyl 3-ethoxypropionate; alkyl 2-oxypropionates such as methyl 2-oxypropionate, ethyl 2-oxypropionate and propyl 2-oxypropionate, e.g., methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate and ethyl 2-ethoxy-2-methylpropionate; methyl pyruvate, ethyl pyruvate, propyl pyruvate, methyl acetoacetate, ethyl acetoacetate, methyl 2-oxobutanate and ethyl 2-oxobutanate;
ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol methyl ether, propylene glycol methyl ether, propylene glycol ethyl ether acetate, propylene glycol propyl ether acetate, ethylcarbitol acetate and butylcarbitol acetate; and
ketones such as methyl ethyl ketone, cyclohexanone, 2-heptanone and 3-heptanone; and aromatic hydrocarbons such as toluene and xylene.

Among these solvents, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butylcarbitol acetate, propylene glycol methyl ether and propylene glycol methyl ether acetate are more preferable.

Two or more of these solvents may be mixed from the viewpoint of the solubility of the dye and alkali-soluble resin and an improvement in coated surface condition. Particularly, mixed solutions including two or more types selected from the aforementioned methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butylcarbitol acetate, propylene glycol methyl ether and propylene glycol methyl ether acetate are preferably used.

—Crosslinking Agent (E)—

The dye-containing curable composition of the invention may contain at least one type of crosslinking agent. The crosslinking agent is used for the purpose of reducing the solubility of the part exposed to light to obtain an image: specifically, the crosslinking agents are activated by an acid or a radical generated from the photopolymerization initiator by irradiation with light or radial rays, and reacted with the above alkali-soluble resin to form crosslinks or combined or polymerized with each other to thereby reduce the solubility of the part exposed to light to obtain an image. The crosslinking agent is also useful for the purpose of curing the pattern sufficiently by heating after an image is formed according to the need.

Therefore, any crosslinking agent may be used without any particular limitation insofar as it can cure a film by a crosslinking or polymerization reaction. Examples of the crosslinking agent include (a) epoxy resins, (b) melamine compounds, guanamine compounds, glycoluril compounds or urea compounds substituted by at least one type selected from a methylol group, alkoxymethyl group and acyloxymethyl group, (c) phenol compounds, naphthol compounds or hydroxyanthracene compounds substituted by at least one type selected from a methylol group, alkoxymethyl group and acyloxymethyl group and (d) polymerizable monomer compounds.

Any material may be used as the epoxy resin (a) insofar as it has an epoxy group and crosslinking ability. Examples of the epoxy resin include divalent glycidyl group-containing low-molecular weight compounds such as bisphenol A diglycidyl ether, ethylene glycol diglycidyl ether, butanediol diglycidyl ether, hexanediol diglycidyl ether, dihydroxybiphenyl diglycidyl ether, diglycidyl phthalate and N,N-diglycidylaniline; trivalent glycidyl group-containing low-molecular weight compounds represented by, for example, trimethylolpropane triglycidyl ether, trimethylolphenol triglycidyl ether and TrisP-PA triglycidyl ether; tetravalent glycidyl group-containing low-molecular weight compounds represented by, for example, pentaerythritol tetraglycidyl ether and tetramethylolbisphenol A tetraglycidyl ether; polyvalent glycidyl group-containing low-molecular weight compounds represented by, for example, dipentaerythritol pentaglycidyl ether and dipentaerythritol hexaglycidyl ether; and glycidyl group-containing high-molecular weight compounds represented by, for example, a polyglycidyl(meth)acrylate and 1,2-epoxy-4-(2-oxyranyl)cyclohexane adducts of 2,2-bis(hydroxymethyl)-1-butanol.

The number of the substituents including a methylol group, alkoxymethyl group or acyloxymethyl group contained in the crosslinking agent (b) is 2 to 6 in the case of a melamine compound, and 2 to 4 in the case of a glycoluril compound, guanamine compound or urea compound. The number of the substituents is preferably 5 to 6 in the case of a melamine compound, and 3 to 4 in the case of a glycoluril compound, guanamine compound or urea compound.

Hereinafter, the aforementioned compound (b), namely, melamine compounds, guanamine compounds, glycoluril compounds and urea compounds are generally referred to as compounds according to (b) (methylol group-containing compounds, alkoxymethyl group-containing compounds or acyloxymethyl group-containing compounds) if necessary.

The methylol group-containing compounds according to (b) may be obtained by heating alkoxymethyl-containing compounds in an alcohol in the presence of an acid catalyst such as hydrochloric acid, sulfuric acid, nitric acid or methanesulfonic acid. The acyloxymethyl group-containing compounds according to (b) may be obtained by mixing methylol group-containing compounds with acyl chloride with stirring in the presence of a basic catalyst.

Specific examples of the compounds having a substituent according to (b) will be given below.

Examples of the melamine compounds include hexamethylolmelamine, hexamethoxymethylmelamine and compounds obtained by methoxymethylating 1 to 5 methylol groups of hexamethylolmelamine or mixtures of these compounds, hexamethoxyethylmelamine, hexaacyloxymethylmelamine and compounds obtained by acyloxymethylating 1 to 5 methylol groups of hexamethylolmelamine or mixtures of these compounds.

Examples of the guanamine compounds include tetramethylolguanamine, tetramethoxymethylguanamine and compounds obtained by methoxymethylating 1 to 3 methylol groups of tetramethylolguanamine or mixtures of these compounds, tetramethoxyethylguanamine, tetraacyloxymethylguanamine and compounds obtained by acyloxymethylating 1 to 3 methylol groups of tetramethylolguanamine or mixtures of these compounds.

Examples of the glycoluril compounds include tetramethylolglycoluril, tetramethoxymethylglycoluril and compounds obtained by methoxymethylating 1 to 3 methylol groups of tetramethylolglycoluril or mixtures of these compounds, and compounds obtained by acyloxymethylating 1 to 3 methylol groups of tetramethylolglycoluril or mixtures of these compounds.

Examples of the urea compounds include tetramethylolurea, tetramethoxymethylurea and compounds obtained by methoxymethylating 1 to 3 methylol groups of tetramethylolurea or mixtures of these compounds, and tetramethoxyethylurea.

These compounds according to (b) may be used either singly or in combinations.

The aforementioned crosslinking agent (c), namely phenol compounds, naphthol compounds or hydroxyanthracene compounds substituted by at least one group selected from a methylol group, alkoxymethyl group and acyloxymethyl group serve to suppress intermixing with an overcoat photoresist and further to raise film strength by thermal crosslinking in the same manner as in the case of the above crosslinking agent (b). Hereinafter, these compounds are generally called compounds according to (c) (methylol group-containing compounds, alkoxymethyl group-containing compounds and acyloxymethyl group-containing compounds) if necessary.

It is necessary that the number of methylol groups, acyloxymethyl groups or alkoxymethyl groups contained in the aforementioned crosslinking agent (c) is at least 2 per one molecule. As the crosslinking agent (c), compounds in which a phenol compound is a skeleton of which the second and fourth positions are all substituted are preferable. Also, as to the compounds containing a naphthol compound or hydroxyanthracene compound as a skeleton, compounds in which the ortho positions and para positions with respect to OH groups are all substituted are preferable. Also, the third or fifth positions of the phenol compound may be unsubstituted or substituted and also, in the naphthol compound, positions other than the ortho position with respect to OH groups may be unsubstituted or substituted.

The methylol group-containing compound according to (c) may be obtained by using, as the raw material, a phenolic OH group-containing compound in which the second and fourth positions with respect to the OH group in the phenolic OH group are occupied by hydrogen atoms and by reacting the phenolic OH group-containing compound with formalin in the presence of a basic catalyst such as sodium hydroxide, potassium hydroxide, ammonia or tetraalkylammonium hydroxide. The alkoxymethyl group-containing compound according to (c) may be obtained by heating the methylol group-containing compound according to (c) in an alcohol in the presence of an acid catalyst such as hydrochloric acid, sulfuric acid, nitric acid or methanesulfonic acid. The acyloxymethyl group-containing compound according to (c) may be obtained by reacting the methylol group-containing compound according to (c) with acyl chloride in the presence of a basic catalyst.

Examples of the skeleton compound in the crosslinking agent (c) include phenol compounds, naphthol compounds and hydroxyanthracene compounds in which the ortho or para position with respect to the phenolic OH group is unsubstituted. As the skeleton compound, for example, each isomer of phenol and cresol, 2,3-xylenol, 2,5-xylenol, 3,4-xylenol, 3,5-xylenol and bisphenols such as bisphenol A, 4,4′-bishydroxybiphenyl, TrisP-PA (manufactured by Honshu Chemical Industry Co., Ltd.), naphthol, dihydroxynaphthalene, 2,7-dihydroxyanthracene or the like is used.

As to specific examples of the above crosslinking agent (c), examples of the phenol compound include trimethylolphenol, tri(methoxymethyl)phenol, compounds obtained by methoxymethylating 1 or 2 methylol groups in trimethylol phenol, trimethylol-3-cresol, tri(methoxymethyl)-3-cresol, compounds obtained by methoxymethylating 1 or 2 methylol groups in trimethylol-3-cresol, dimethylolcresol such as 2,6-dimethylol-4-cresol, tetramethylol bisphenol A, tetramethoxymethyl bisphenol A, compounds obtained by methoxymethylating 1 to 3 methylol groups in tetramethylol bisphenol A, tetramethylol-4,4′-bishydroxybiphenyl, tetramethoxymethyl-4,4′-bishydroxybiphenyl, hexamethylol compounds of TrisP-PA, hexamethoxymethyl compounds of TrisP-PA, compounds obtained by methoxymethylating 1 to 5 methylol groups in a hexamethylol compounds of TrisP-PA and bishydroxymethylnaphthalenediol.

Examples of the hydroxyanthracene compound include 1,6-dihydroxymethyl-2,7-dihydroxyanthracene and examples of the acyloxymethyl group-containing compound include compounds obtained by acyloxymethylating a part or all of the methylol groups in the above methylol group-containing compounds.

Among these compounds, preferable examples include trimethylol phenol, bishydroxymethyl-p-cresol, tetramethylol bisphenol A, hexamethylol compounds of TrisP-PA (manufactured by Honshu Chemical Industry Co., Ltd.) or phenol compounds in which methylol groups of these hexamethylol compounds are substituted with an alkoxymethyl group or both of a methylol group and an alkoxymethyl group.

These compounds according to (c) may be used either singly or in combinations.

Next, the aforementioned polymerizable monomer compound (d) will be explained. Compounds having at least one addition-polymerizable ethylene group and a boiling point of 100° C. or more under normal pressure are preferable as the polymerizable compound.

Examples of the polymerizable monomer compound may include monofunctional acrylates or methacrylates such as a polyethylene glycol mono(meth)acrylate, polypropylene glycol mono(meth)acrylate and phenoxyethyl(meth)acrylate, polyethylene glycol di(meth)acrylate, trimethylolethanetri(meth)acrylate, neopentyl glycol di(meth)acrylate, pentaerythritol tri(meth)acrylate, pentaerythritol tetra(meth)acrylate, dipentaerythritol hexa(meth)acrylate, hexanediol(meth)acrylate, trimethylolpropanetri(acryloyloxypropyl)ether, tri(acryloyloxyethyl)isocyanurate, compounds obtained by (meth)acrylating polyfunctional alcohols such as glycerin or trimethylolethane after ethylene oxide or propylene oxide is added to these alcohols, polyfunctional acrylates or methacrylates such as urethaneacrylates as described in each publication of JP-B No.48-41708, JP-B No. 50-6034 and JP-A No. 51-37193, polyester acrylates as described in each publication of JP-A No. 48-64183, JP-B No. 49-43191 and JP-B No. 52-30490 and epoxyacrylates which are reaction products of epoxy resins and (meth)acrylic acids. Also, examples of the polymerizable monomer compound include those reported as photocurable monomers and oligomers in J. Japan Adhesive Association, Vol. 20, No. 7, pp 300-308.

When the crosslinking agent is contained, the total content of the aforementioned crosslinking agents (a) to (d) in the dye-containing curable composition is preferably 1 to 70 mass %, more preferably 5 to 50 mass %, and particularly preferably 7 to 30 mass % based on the solid content of the composition though it differs depending on the type of the raw material.

—(F) Others—

(Thermal Polymerization Inhibitor)

In addition to the above compounds, a thermal polymerization inhibitor is preferably further added to the dye-containing composition of the invention. For example, hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenzoimidazole, and the like are useful.

(Various Additives)

The dye-containing curable composition of the invention may, according to the need, contain various additives, for example, a filler, high-molecular weight compounds other than the above, surfactant, adhesion promoter, antioxidant, ultraviolet absorber and anticoagulant. Also, as required, a color-fading preventive for dye may be added.

Specific examples of the aforementioned various examples may include fillers such as glass and alumina; high-molecular weight compounds other than binder resins such as a polyvinyl alcohol, polyacrylic acid, polyethylene glycol monoalkyl ether and polyfluoroalkylacrylate; surfactants such as a nonionic type, cationic type and anionic type; adhesion promoters such as vinyltrimethoxysilane, vinyltriethoxysilane, vinyltris(2-methoxyethoxy) silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane and 3-mercaptopropyltrimethoxysilane; antioxidants such as 2,2-thiobis(4-methyl-6-t-butylphenol) and 2,6-di-t-butylphenol; ultraviolet absorbers such as 2-(3-t-butyl-5-methyl-2-hydroxyphenyl)-5-chlorobenzotriazole and alkoxybenzophenone; and anticoagulants such as sodium polyacrylates.

Also, for promoting the alkali-solubility of the non-cured part and further improving the developing ability of the dye-containing curable composition of the invention, an organic carboxylic acid and preferably a low-molecular weight organic carboxylic acid having a molecular weight of 1000 or less may be added to the composition.

Examples of the organic carboxylic acid include aliphatic monocarboxylic acids such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; aliphatic tricarboxylic acid such as tricarbarilic acid, aconitic acid and camphoronic acid; aromatic monocarboxylic acids such as benzoic acid, toluic acid, cuminic acid, hemellitic acid and mesitylenic acid; aromatic polycarboxylic acids such as phthalic acid, isophthalic acid, terephthalic acid, trimellitic acid, trimesic acid, mellophanic acid and pyromelitic acid; and other carboxylic acids such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid and umbellic acid.

The dye-containing curable composition of the invention may be preferably used for forming color pixels of, for example, color filters and electroluminescence color filters which are used liquid crystal display devices and solid imaging devices (for example, CCDs and CMOSs) and also, for producing printing ink, ink jet ink and paints.

Color Filter and Method of Producing the Color Filter

Next, the color filter of the invention will be described in detail by way of a method of producing the color filter.

In the method of producing a color filter according to the invention, the already mentioned dye-containing curable composition of the invention is used. The color filter of the invention includes at least a phthalocyanine compound (dye) represented by the aforementioned Formula (I) of (B) and further, may include the above-mentioned various components which can be contained in usual dye-containing curable compositions.

The color filter of the invention may be manufactured in the following manner: the aforementioned dye-containing curable composition of the invention is used, this dye-containing curable composition is applied to a support by a coating method such as rotation coating, cast coating and roll coating to form a radiation-curable composition layer and this layer is exposed to light through a predetermined mask pattern and developed using a developer to form a negative type or positive type color pattern, whereby the color filter can be manufactured most preferably (image forming process). At this time, a curing process of curing the formed color pattern by heating and/or exposure may be provided. The exposure may be carried out using light or radiation and as this light or radiation, particularly g-rays, h-rays or i-rays are preferably used. When the dye-containing curable composition is structured as a positive type, a process of post-baking the color pattern is usually provided after the image forming process.

In the production of the color filter, the above image forming process (and a curing process according to the need) is repeated in accordance with the number of hues in the case of a negative type, and the above image forming process and post-baking process are repeated in accordance with the number of hues in the case of a positive type, whereby a color filter structured to have a desired number of hues can be manufactured.

Examples of the support include soda glass, PYREX glass and quartz glass which are used, for example, liquid crystal display elements and those obtained by applying a transparent conductive film to these glasses, photoelectric transfer element substrates, for example, silicon substrates, used, for example, imaging devices and complementary metal oxide semiconductors (CMOS). These supports are sometimes provided with a black stripe formed to separate each pixel.

Also, an undercoat layer may be formed on these supports according to the need to improve the adhesion to the upper layer, to prevent the diffusion of materials or to flatten the surface of the substrate.

Any developer may be used as the developer insofar as it has a composition which dissolves the uncured part of the dye-containing curable composition of the invention, but leaves the cured part undissolved. Specifically, combinations of various organic solvents or aqueous alkaline solutions may be used. Examples of the organic solvent include the above solvents used when the dye-containing curable composition of the invention is prepared.

As the aqueous alkaline solution, an aqueous alkaline solution obtained by dissolving an alkaline compound such as sodium hydroxide, potassium hydroxide, sodium carbonate, sodium silicate, sodium methasilicate, aqueous ammonia, ethylamine, diethylamine, dimethylethanolamine, tetramethylammonium hydroxide, tetraethylammonium hydroxide, choline, pyrrole, piperidine or 1,8-diazabicyclo-[5.4.0]-7-undecene in a concentration of 0.001 to 10 mass % and preferably 0.01 to 1 mass % is preferable. When a developer of such an aqueous alkaline solution is used, the developed film is washed with water in usual.

The color filter of the invention is preferably used for liquid display devices and solid-state imaging elements and particularly, CCD elements, CMOS and devices for electroluminescence which have high resolution such as those having one million or more pixels. The color filter of the invention may be used, for example, as a color filter disposed between the light receptor section of each pixel constituting a CCD and a microlens for converging light.

Generally, as mentioned above, if application of a phthalocyanine-type dye to a color filter is intended, the spectral characteristics are unsatisfactory, and also, phthalocyanine-type dyes are poor in solubility. It has thus been so far regarded as difficult to produce a color filter with a coating method using a dye-containing curable composition. Also, when a dye-containing curable composition that contains a phthalocyanine-type dye is stored in the state of a solution, for example, precipitation occurs with time and preserving stability of the composition is deteriorated, and thus is poor in practicability. In the invention, a phthalocyanine-type dye having the structure represented by Formula (I) is used and therefore, better spectral characteristics (particularly, hue in the visible portion of the long wavelength region suitable for a green or blue color filter) and solvent solubility are secured. Also, since solvent solubility is increased, precipitation of dye from the dye-containing curable composition and from the coating film is reduced and high heat resistance and light fastness can be maintained. This makes it possible to obtain a stable dye-containing curable composition and a high performance color filter.

### EXAMPLES

The present invention will be explained in more detail by way of examples. However, the following Examples should not be construed as limiting the scope of the invention. In these examples, all designations of “parts” indicate parts by mass, unless otherwise noted.

### Example 1

1) Preparation of a resist solution

| | |
|---|---|
| Ethyl lactate (EL) | 59.0 parts |
| Alkali-soluble resin (propylene glycol monomethyl ether | 24.4 parts |
| acetate/EL(=1/1; mass ratio) containing 41% of | |
| benzylmethacrylate/methacrylic acid/2- | |
| hydroxyethylmethacrylate copolymer | |
| (=60:20:20 [molar ratio]) solution | |
| Dipentaerythritol hexaacrylate | 16.0 parts |
| Polymerization inhibitor (p-methoxyphenol) | 0.006 parts |
| Photopolymerization initiator TAZ-107 | 0.58 parts |
| (Midori Kagaku Co., Ltd.) | |

The above components were mixed and dissolved to prepare a resist solution.

2) Preparation of a Glass Substrate with an Undercoat Layer

A glass substrate (Coning 1737) was subjected to ultrasonic cleaning using aqueous 0.5% NaOH and then washed with water, followed by dehydration baking (200° C./20 minutes). Then, the resist solution obtained above 1) was applied to the washed glass substrate in a film thickness of 2 μm by a spin coater and dried at 220° C. under heating for one hour to form a cured film (undercoat layer).

3) Preparation of a Dye Resist Solution (Negative Type Dye-Containing Curable Composition)

9.0 g of the resist solution obtained in the above 1) and 1.0 g of the aforementioned exemplified compound (3) (phthalocyanine compound represented by Formula (I)) as a dye were mixed and dissolved to obtain a dye resist solution (solution of the dye-containing curable composition (negative type) of the invention).

4) Exposure/Development of the Dye-Containing Curable Composition (Image Forming Process)

The dye resist solution obtained in the above 3) was applied to the undercoat layer of the glass substrate with an undercoat layer which was obtained in the above 2), in a film thickness of 1.0 μm by a spin coater and prebaked at 110° C. for 120 seconds.

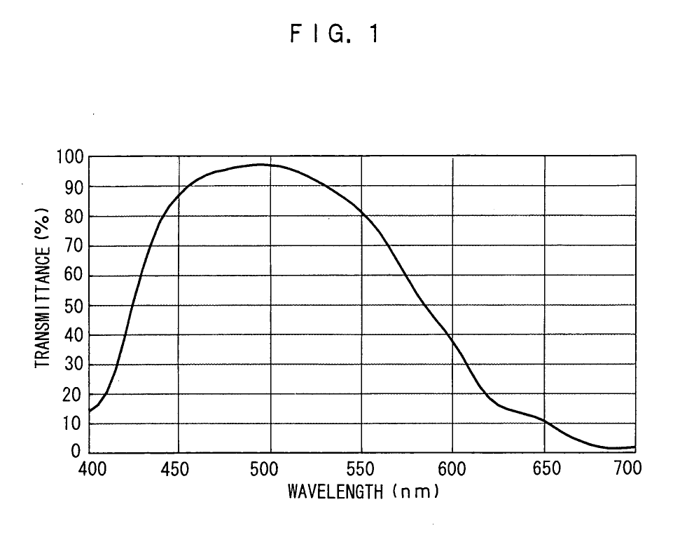

Here, the spectrum of the prebaked dye resist film was measured by a chromaticity meter (trade name: MCPD-1000, manufactured by Otsuka Electronics Co., Ltd.). As a result, the resist film had large absorption for light having a wavelength as long as 600 nm or more, exhibiting a character shown by a better transmission curve. The spectrum obtained at this time is shown in FIG. 1.

Next, an exposure apparatus was used to apply light having a wavelength of 365 nm to the coating film at an exposure dose of 500 mJ/cm² through a mask having a line width of 20 μm. After the light was applied, the coating film was developed using a developer (trade name: CD-2000, manufactured by Fuji Film Arch Co.) at 25° C. for 40 seconds. After that, the coating film was then rinsed by a water stream for 30 seconds, followed by spray drying to obtain a cyan pattern image. The image formation was confirmed by a usual method using an optical microscope and by observation of a SEM photography. The formed pattern image exhibited a sharp rectangular profile.

5) Evaluation

The following methods were used to evaluate the solubility, light fastness and heat resistance of a dye and pattern shape. The results of evaluation are shown in Table 3 below.

—Solubility—

The solubility of the dye used above (exemplified compound (3); a phthalocyanine compound represented by Formula (I)) was evaluated by visual observation according to the following criteria from the degree of solubility when 1.0 g of the exemplified compound (3) was dissolved in 9.0 g of the resist solution in the above “3) Preparation of a dye resist solution”.

(Evaluation Criteria)

A: Dye was dissolved completely.
B: A little residual dye left undissolved was found.
C: A lot of an undissolved dye was found.
   —Heat resistance—

The glass substrate coated with the dye resist solution was placed on a hot plate such that its surface was in contact with the hot plate and heated at 200° C. for one hour to measure a change in chromaticity, namely ΔEab* value, before and after the substrate was placed, by using a chromaticity meter (trade name: MCPD-1000, manufactured by Otsuka Electronics Co., Ltd.). The obtained ΔEab* value was adopted as an index showing the degree of heat resistance and evaluated based on the following criteria. The smaller the ΔEab* value is, the higher the heat resistance is.

(Evaluation Criteria)

A: ΔEab* was 5 or less.
B: ΔEab* exceeded 5 and was less than 10.
C: ΔEab* was 10 or more.
   —Light Fastness—

The glass substrate coated with the dye resist solution was irradiated with 50,000 Lux light from a xenon lamp for 10 hours (corresponding to 500,000 Lux·h) and then, a change in chromaticity, namely ΔEab* value, before and after the irradiation was measured. The obtained ΔEab* value was adopted as an index showing the degree of heat resistance and evaluated based on the following criteria. The smaller the ΔEab* value is, the higher the heat resistance is.

(Evaluation Criteria)

A: ΔEab* was 3 or less.
B: ΔEab* exceeded 3 and was less than 10.
C: ΔEab* was 10 or more.
   —Pattern Shape—

The sectional shape of the formed 20 μm pattern image was measured by observing a photography of a SEM image visually and evaluated according to the following criteria.
A: The pattern section had a sharp rectangular.
B: The pattern section was found to have a slightly taper shape.
C: The pattern section had a taper shape.

### Examples 2 to 10

The same procedures as in Example 1 were conducted except that the dye used in “3) Preparation of a dye resist solution” was altered to each of the dyes described in Table 3 shown below, to form a pattern image, which was evaluated in the same manner as in Example 1. The results of evaluation are shown in Table 3 below.

### Comparative Examples 1 to 3

The same procedures as in Example 1 were conducted except that the dye used in “3) Preparation of a dye resist solution” was altered to each of the dyes described in Table 3 shown below (comparative compounds 1 to 3 in Table 2), to form a pattern image, which was evaluated in the same manner as in Example 1. The results of evaluation are shown in Table 3 below.

TABLE 2

| | | |
|---|---|---|
| R | Substitution position of R | M |

| | | |
|---|---|---|
| Comparative compound 1 | Unsubstituted | Cu |
| Comparative compound 2 | Unsubstituted | Zn |
| Comparative compound 3 | Unsubstituted | Co |

*R and M are those shown in Formula (I).

TABLE 3

| | | | Heat | Light | |
|---|---|---|---|---|---|
| | | Solu- | resis- | fast- | Pattern |
| | Dye*¹ | bility | tance | ness | shape |
| Example 1 | Exemplified compound (3) | A | A | A | A |
| Example 2 | Exemplified compound (4) | A | A | A | A |
| Example 3 | Exemplified compound (7) | A | A | A | A |
| Example 4 | Exemplified compound (8) | B | A | A | A |
| Example 5 | Exemplified compound (9) | A | B | A | A |
| Example 6 | Exemplified compound (10) | B | A | A | A |
| Example 7 | Exemplified compound (13) | A | A | A | A |
| Example 8 | Exemplified compound (18) | A | A | A | A |
| Example 9 | Exemplified compound (19) | A | A | A | A |
| Example 10 | Exemplified compound (2) | A | B | B | A |
| Comparative | Comparative compound 1 | C | — | — | — |
| Example 1 | | | | | |
| Comparative | Comparative compound 2 | C | — | — | — |
| Example 2 | | | | | |
| Comparative | Comparative compound 3 | C | — | — | — |
| Example 3 | | | | | |

*¹The exemplified compounds described in the column of “Dye” in Examples are phthalocyanine compounds represented by Formula (I).

As shown in Table 3, the phthalocyanine compounds represented by Formula (I) had high solubility and were resistant to precipitation from a dye-containing curable composition prepared in a liquid state and from the applied film. The dye-containing curable composition and color filter including this phthalocyanine compound as a dye were superior in heat resistance and light fastness and the formed pattern image exhibited a sharp rectangular profile. On the other hand, phthalocyanine type dyes having no heterocyclic group at the α- and β-positions had very poor solubility and therefore, could not stand the subsequent use, with the result that no pattern image (color filter) could not be formed.

### Example 11

1) Preparation of a dye resist solution (positive type dye-containing
curable composition)

| | | |
|---|---|---|
| Ethyl lactate (EL) | 15 | parts |
| Propylene glycol monomethyl ether acetate (PGMEA) | 15 | parts |
| Resin P-1 shown below | 3 | parts |
| Naphthoquinonediazide compound N-1 shown below | 1.8 | parts |
| Hexamethoxymethylol melamine (crosslinking agent) | 0.6 | parts |
| Photo acid generator TAZ-107 (manufactured by | 1.2 | parts |
| Midori Kagaku Co., Ltd.) | | |
| Fluorine type surfactant F-475 (manufactured by | 0.0005 | parts |
| Dainippon Ink and Chemicals Incorporated) | | |
| Dye (the above exemplified compound (3)) | 1.5 | parts |
| (phthalocyanine compound represented by Formula (I)) | | |

The above components were mixed and dissolved to prepare a dye resist solution (solution containing the dye-containing curable composition (positive type) of the invention).

—Synthesis of Resin P-1—

70.0 g of benzylmethacrylate, 13.0 g of methacrylic acid, 17.0 g of 2-hydroxyethylmethacryate, 300 g of ethyl lactate and 300 g of propylene glycol monomethyl ether acetate were prepared in a three-neck flask. Then, a stirrer, a reflux condenser and a thermometer were fitted to the flask. A polymerization initiator (trade name: V-65, manufactured by Wako Pure Chemical Industries Ltd.) was added in a catalytic amount to the mixture, which was then stirred for 10 hours in a nitrogen stream at 65° C. The obtained resin solution was added dropwise to 20 L of ion exchange water with vigorously stirring, to obtain a white powder. The resulting white powder was dried under vacuum at 40° C. for 20 hours to obtain 140 g of a resin P-1. The molecular weight of this resin P-1 was measured by GPC, to find that the weight average molecular weight Mw=27,000 and the number average molecular weight Mn=10,500.

—Synthesis of a Naphthoquinonediazide Compound N-1—

42.45 g of TrisP-PA (manufactured by Honshu Chemical Industry Co., Ltd.), 61.80 g of o-naphthoquinonediazide-5-sulfonyl chloride and 300 ml of acetone were prepared in a three-neck flask, to which 24.44 g of triethylamine was added dropwise at ambient temperature for one hour. After the addition was finished, the mixture was further stirred for 2 hours and the obtained reaction solution was poured into a large amount of water with stirring. The precipitated naphthoquinonediazide sulfonate was collected by suction filtration and dried under vacuum at 40° C. for 24 hours to obtain a naphthoquinonediazide compound N-1.

2) Exposure/Development or Other Treatments and Evaluation of the Dye-Containing Curable Composition

A cyan pattern image was obtained by carrying out coating, prebaking, irradiation, developing, rinsing and drying in the same manner as in Example 1 and then heated at 180° C. for 5 minutes. Also, the heat resistance, light fastness and pattern shape were evaluated in the same manner as in Example 1 and also the solubility of the dye (exemplified compound (3)) was evaluated visually according to the same criteria as in Example 1 from the degree of solubility when the dye was dissolved in the above “1) Preparation of a dye resist solution (positive type dye-containing curable composition)”.

### Examples 12 to 20, Comparative Examples 4 to 6

Pattern images were formed and evaluated in the same manner as in Example 11 except that, in Example 11, the dye used in “1) Preparation of a dye resist solution (positive type dye-containing curable composition)” was altered to each of the dyes described in Table 4 shown below. The results of evaluation are shown in Table 4.

TABLE 4

| | | | Heat | Light | |
|---|---|---|---|---|---|
| | | Solu- | resis- | fast- | Pattern |
| | Dye*¹ | bility | tance | ness | shape |
| Example 11 | Exemplified compound (3) | A | A | A | A |
| Example 12 | Exemplified compound (4) | A | A | A | A |
| Example 13 | Exemplified compound (1) | A | A | A | A |
| Example 14 | Exemplified compound (2) | B | A | A | A |
| Example 15 | Exemplified compound (11) | A | B | A | A |
| Example 16 | Exemplified compound (12) | B | A | A | A |
| Example 17 | Exemplified compound (14) | A | A | A | A |
| Example 18 | Exemplified compound (16) | A | A | A | A |
| Example 19 | Exemplified compound (17) | A | A | A | A |
| Example 20 | Exemplified compound (20) | A | B | B | A |
| Comparative | Comparative compound 1 | C | — | — | — |
| Example 4 | | | | | |
| Comparative | Comparative compound 2 | C | — | — | — |
| Example 5 | | | | | |
| Comparative | Comparative compound 3 | C | — | — | — |
| Example 6 | | | | | |

*¹The exemplified compounds described in the column of “Dye” in Examples are phthalocyanine compounds represented by Formula (I).

Also as shown in Table 3, in the case of the compositions having a positive type structure, as shown in Examples 11 to 20, the solubility was high, each composition was superior in heat resistance and light fastness, and the formed pattern image exhibited a rectangular profile.

### Examples 21 to 40

The same procedures as in Examples 1 to 20 were conducted except that each glass substrate used in Examples 1 to 20 was altered to a silicon wafer substrate to form a pattern image. Then, using an i-ray reduced projection exposure apparatus, the coating film was exposed to light in a 2×2 μm square pattern at an exposure dose of 500 mj/cm². After the irradiation was finished, the coating film was developed using a 60% CD-2000 (manufactured by Fuji Film Arch Co.) developer at 23° C. for 60 seconds. Thereafter, the coating film was rinsed in a water stream for 30 seconds and spray-dried. A pattern suitable for a CCD color filter which had a square shape and a rectangular section was thereby obtained.

The invention can provides a dye-containing curable composition which has good spectral characteristics (absorption coefficient) when obtaining a cyan color, and, for example, a green color by combining a yellow dye type or a blue color by combining a violet dye type, has a high solvent-solubility and is superior in heat resistance and light fastness.

The invention also provides a color filter which has a sharp pattern (for example, a good rectangular shape) and is structured to have high resolution, has spectral characteristics exhibiting a good hue, and is superior in heat resistance and light fastness. Further, the invention provides a method of producing a color filter, that allows the color filter to be produced at a high level of productivity.

1. A dye-containing curable composition comprising at least an alkali-soluble resin, a dye, and a photosensitive compound, wherein;
the dye is a phthalocyanine compound represented by the following Formula (I): 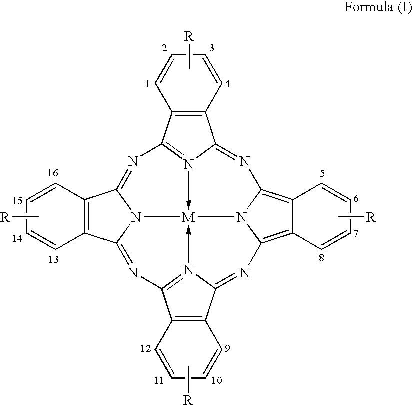
wherein M represents a metal atom, a metal oxide, a metal chloride, or a hydrogen atom; R represents a heterocyclic group containing, as heteroatoms, two or more nitrogen atoms, or one or more of each of nitrogen and sulfur atoms; and the four R's are respectively bonded to a carbon atom at the α-positions (in Formula (I), 1 or 4, 5 or 8, 9 or 12, and 13 or 16) or at the β-positions (in Formula (I), 2 or 3, 6 or 7, 10 or 11, and 14 or 15) in a phthalocyanine nucleus at the same time.

2. The dye-containing curable composition of claim 1, wherein R in Formula (I) is a group selected from the group consisting of a substituted or unsubstituted pyrazolyl group, a substituted or unsubstituted imidazolyl group, a substituted or unsubstituted 1,2,3-triazolyl group, a substituted or unsubstituted 1,2,4-triazolyl group, a substituted or unsubstituted tetrazolyl group, a substituted or unsubstituted indazolyl group, a substituted or unsubstituted benzimidazolyl group, a substituted or unsubstituted benzotriazolyl group, a substituted or unsubstituted thiazolyl group, a substituted or unsubstituted benzothiazolyl group, a substituted or unsubstituted purinyl group, and a substituted or unsubstituted pyrimidinyl group.

3. The dye-containing curable composition of claim 1, wherein R in Formula (I) is a group selected from the group consisting of a pyrazolyl group, a 3-methylpyrazolyl group, a 3,5-dimethylpyrazolyl group, a benzimidazolyl group, a 5,6-dimethylbenzimidazolyl group, and a 4,6-dimethylpyrimidinyl group.

4. The dye-containing curable composition of claim 1, wherein the four R's in Formula (I) are bonded to the α-position carbon atoms of the phthalocyanine nucleus.

5. The dye-containing curable composition of claim 1, wherein the phthalocyanine compound represented by Formula (I) is contained in an amount of 1 to 80 mass % based on the total solid of the dye-containing curable composition.

6. The dye-containing curable composition of claim 1, wherein the phthalocyanine compound represented by Formula (I) is contained in an amount of 3 to 50 mass % based on the total solid of the dye-containing curable composition.

7. The dye-containing curable composition of claim 1, further comprising a solvent, wherein said solvent is a mixed solution including two or more types selected from the group consisting of methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butylcarbitol acetate, propylene glycol methyl ether, and propylene glycol methyl ether acetate.

8. The dye-containing curable composition of claim 1, further comprising a crosslinking agent.

9. The dye-containing curable composition of claim 1, further comprising a thermopolymerization inhibitor.

10. A method of producing a color filter, the method comprising applying the dye-containing curable composition according to claim 1 to a support, then exposing the applied composition to light through a mask, and then developing to form a pattern image.

11. A method of producing a color filter, the method comprising applying the dye-containing curable composition according to claim 2 to a support, then exposing the applied composition to light through a mask, and then developing to form a pattern image.

12. A method of producing a color filter, the method comprising applying the dye-containing curable composition according to claim 3 to a support, then exposing the applied composition to light through a mask, and then developing to form a pattern image.

13. A method of producing a color filter, the method comprising applying the dye-containing curable composition according to claim 4 to a support, then exposing the applied composition to light through a mask, and then developing to form a pattern image.

14. A method of producing a color filter, the method comprising applying the dye-containing curable composition according to claim 5 to a support, then exposing the applied composition to light through a mask, and then developing to form a pattern image.

15. A method of producing a color filter, the method comprising applying the dye-containing curable composition according to claim 6 to a support, then exposing the applied composition to light through a mask, and then developing to form a pattern image.

16. A method of producing a color filter, the method comprising applying the dye-containing curable composition according to claim 7 to a support, then exposing the applied composition to light through a mask, and then developing to form a pattern image.

17. A color filter comprising a phthalocyanine compound represented by the following Formula (I): 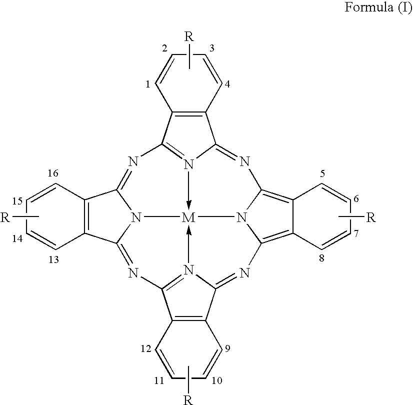
wherein M represents a metal atom, a metal oxide, a metal chloride, or a hydrogen atom; R represents a heterocyclic group containing, as heteroatoms, two or more nitrogen atoms, or one or more of each of nitrogen and sulfur atoms; and the four R's are respectively bonded to a carbon atom at the α-positions (in Formula (I), 1 or 4, 5 or 8, 9 or 12, and 13 or 16) or at the β-positions (in Formula (I), 2 or 3, 6 or 7, 10 or 11, and 14 or 15) in a phthalocyanine nucleus.

18. The color filter of claim 17, wherein R in Formula (I) is a group selected from the group consisting of a substituted or unsubstituted pyrazolyl group, a substituted or unsubstituted imidazolyl group, a substituted or unsubstituted 1,2,3-triazolyl group, a substituted or unsubstituted 1,2,4-triazolyl group, a substituted or unsubstituted tetrazolyl group, a substituted or unsubstituted indazolyl group, a substituted or unsubstituted benzimidazolyl group, a substituted or unsubstituted benzotriazolyl group, a substituted or unsubstituted thiazolyl group, a substituted or unsubstituted benzothiazolyl group, a substituted or unsubstituted purinyl group, and a substituted or unsubstituted pyrimidinyl group.

19. The color filter of claim 17, wherein R in Formula (I) is a group selected from the group consisting of a pyrazolyl group, a 3-methylpyrazolyl group, a 3,5-dimethylpyrazolyl group, a benzimidazolyl group, a 5,6-dimethylbenzimidazolyl group, and a 4,6-dimethylpyrimidinyl group.

20. The color filter of claim 17, wherein the four R's in Formula (I) are bonded to the α-position carbon atoms of the phthalocyanine nucleus.
